(19) United States
(12) Patent Application Publication
(10) Pub. No.: US 2024/0287383 A1
(43) Pub. Date: Aug. 29, 2024

(54) SILICON-ETCHANT COMPOSITION AND METHOD OF FORMING PATTERN USING THE SAME

(71) Applicant: DONGWOO FINE-CHEM CO., LTD., Jeollabuk-do (KR)

(72) Inventors: JIN KYU ROH, Jeollabuk-do (KR); KYU SANG AHN, Jeollabuk-do (KR); HYO JOONG YOON, Jeollabuk-do (KR)

(21) Appl. No.: 18/441,167

(22) Filed: Feb. 14, 2024

(30) Foreign Application Priority Data
Feb. 23, 2023 (KR) 10-2023-0024149

(51) Int. Cl. C09K 13/00; H01L 21/306; H01L 21/308

(52) U.S. Cl. CPC C09K 13/00; H01L 21/30604; H01L 21/308

(57) ABSTRACT

A silicon-etchant composition according to an embodiment may include quaternary alkyl ammonium hydroxide, an amine-based compound, and two or more types of nonionic surfactants represented by Chemical Formula 1 and having different lengths of a hydrophilic group. Accordingly, the silicon-etchant composition having improved etch rate and etching selectivity is provided.

### CROSS-REFERENCE TO RELATED APPLICATION AND CLAIM OF PRIORITY

This application claims the benefit under 35 USC § 119 of Korean Patent Application No. 10-2023-0024149 filed on Feb. 23, 2023, in the Korean Intellectual Property Office (KIPO), the entire disclosure of which is incorporated herein by reference for all purposes.

### BACKGROUND

### 1. Field

The present invention relates to a silicon-etchant composition and a method of forming a pattern using the same. More particularly, the present invention relates to a silicon-etchant composition including an etching agent and a solvent, and a method of forming a pattern using the same.

### 2. Description of the Related Art

For example, in a semiconductor device such as DRAM, NAND flash memory and logic devices, developments to implement a large capacity while drastically reducing a critical dimension (CD) has been continued.

In the semiconductor device above, a layer or a pattern formed of silicon such as polysilicon is widely used as a material for a gate electrode, a capacitor electrode, a conductive contact, a wiring, etc. When the gate electrode or the wiring is formed through a direct etching of a metal film, a pattern having a desired fine dimension may not be easily obtained due to a limitation of an etching resolution. Accordingly, a process using a polysilicon layer is being researched.

To perform a highly reliable semiconductor device process, both a fast etching rate for a removal target and an etching uniformity are required. However, when performing the etching process, an increase of the etching rate for the removal target may accelerate an etching of a protective film material.

Accordingly, developments of an etchant composition capable of improving an etching selectivity while maintaining the etch rate and the etching uniformity for forming fine-dimensional patterns are needed in a silicon layer etching process

### SUMMARY

According to an aspect of the present invention, there is provided a silicon-etchant composition having improved etching efficiency and reliability.

According to an aspect of the present invention, there is provided a method of forming a pattern using the silicon-etchant composition.
(1) A silicon-etchant composition, including: a quaternary alkyl ammonium hydroxide; an amine-based compound; and a nonionic surfactant, wherein the nonionic surfactant includes at least two selected from the group consisting of a first nonionic surfactant represented by Chemical Formula 1 where n is 1 to 2, a second nonionic surfactant represented by Chemical Formula 1 where n is 3 to 5, a third nonionic surfactant represented by Chemical Formula 1 where n is 6 to 8:

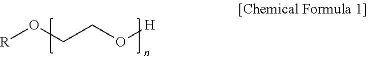

wherein, in Chemical Formula 1, R is a C3 to C18 linear or branched alkyl group, a C3 to C18 cyclic alkyl group, or a C6 to C18 aryl group.
(2) The silicon-etchant composition of the above (1), wherein the nonionic surfactant includes the second nonionic surfactant, and further includes at least one of the first nonionic surfactant and the third nonionic surfactant.
(3) The silicon-etchant composition of the above (1), wherein a content of the nonionic surfactant is in a range from 0.01 wt % to 0.2 wt % based on a total weight of the composition.
(4) The silicon-etchant composition of the above (2), wherein the nonionic surfactant includes the first nonionic surfactant and the second nonionic surfactant, and a weight ratio of the first nonionic surfactant to the second nonionic surfactant is in a range from 0.1 to 0.2.
(5) The silicon-etchant composition of the above (4), wherein a weight ratio of the first nonionic surfactant to the second nonionic surfactant is in a range from 0.12 to 0.17.
(6) The silicon-etchant composition of the above (2), wherein the nonionic surfactant includes the second nonionic surfactant and the third nonionic surfactant, and a weight ratio of the third nonionic surfactant to the second nonionic surfactant is in a range from 0.08 to 0.17.
(7) The silicon-etchant composition of the above (6), wherein a weight ratio of the third nonionic surfactant to the second nonionic surfactant is in a range from 0.10 to 0.15.
(8) The silicon-etchant composition of the above (1), wherein the nonionic surfactant does not include a nonionic surfactant represented by Chemical Formula 1 where n is 8.
(9) The silicon-etchant composition of the above (1), wherein, in Chemical Formula 1, R is a phenyl group, a naphthyl group, a methylphenyl group or an octylphenyl group.
(10) The silicon-etchant composition of the above (1), wherein a content of the quaternary alkyl ammonium hydroxide is in a range from 1 wt % to 20 wt % based on a total weight of the composition.
(11) The silicon-etchant composition of the above (1), wherein a content of the amine-based compound is in a range from 1 wt % to 30 wt % based on a total weight of the composition.
(12) A method of forming a pattern, including: forming a silicon-containing layer on a substrate; partially forming a silicon protective layer on the silicon-containing layer; and etching the silicon-containing layer using the silicon-etchant composition of the etchant composition according to the above-described embodiments.
(13) The method of the above (12), wherein the silicon protective film is used as an etch mask.
(14) The method of the above (12), wherein etching the silicon-containing layer includes forming a gate pattern by etching the silicon-containing layer.

A silicone etchant composition according to exemplary embodiments of the present invention may include two or more types of nonionic surfactants having different hydrophilic group lengths. The two or more types of the nonionic surfactants may provide different functions from each other from aspects of increasing an etching rate of the silicon-etchant composition, improving an etching uniformity, or improving a surface roughness of an etching object.

The silicon-etchant composition may contain a combination of the two or more types of the nonionic surfactants with different functions, so that the etching rate of the silicon-etchant composition may be increased and uniform etching may be provided even when being applied to an etching object with a narrow pattern size (e.g., a silicon wafer). Further, a surface roughness of the etching object and etching residues on a surface of the etching object after the etching may be reduced.

The nonionic surfactant includes a second nonionic surfactant having a medium length hydrophilic group, and may further include a first nonionic surfactant or a third nonionic surfactant having a long or short hydrophilic group in a predetermined content ratio. Accordingly, the etching rate and the etching uniformity of the silicon-etchant composition may be further improved.

A highly reliable nano-scale semiconductor device pattern may be formed using the silicon-etchant composition according to exemplary embodiments of the present invention.

### BRIEF DESCRIPTION OF THE DRAWINGS

FIGS. 1 to 7 are schematic cross-sectional views illustrating a method of forming a pattern in accordance with exemplary embodiments.

### DETAILED DESCRIPTION OF THE EMBODIMENTS

A silicon-etchant composition according to embodiments of the present invention may include a quaternary alkyl ammonium hydroxide, an amine-based compound, and two or more types of nonionic surfactants. The silicon-etchant composition may rapidly and uniformly etch a silicon layer while substantially causing no etching residues on a surface of an etching object.

Additionally, a method of forming a pattern using the etchant composition is provided.

The term “silicon” used herein may refer to polysilicon or amorphous silicon. Hereinafter, embodiments of the present invention will be described in detail.

The quaternary alkyl ammonium hydroxide may serve as a main etching agent to remove an etching object layer, e.g. a silicon layer during an etching process. For example, the quaternary alkyl ammonium hydroxide may be dissociated in a solution to generate hydroxide ions, thereby increasing a pH of the etchant composition to etch the silicon layer.

The quaternary alkyl ammonium hydroxide may include a compound represented by Chemical Formula 2.

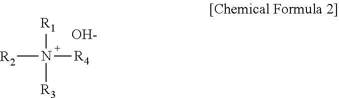

In Chemical Formula 2, R₁, R₂, R₃ and R₄ are each independently an alkyl group or an aryl group having 1 to 8 carbon atoms, and in some embodiments, may be an alkyl group having 1 to 4 carbon atoms. When the carbon number of R₁, R₂, R₃ and R₄ is within the above range, the hydroxide ion dissociation of the quaternary alkyl ammonium hydroxide may be improved. The alkyl group or the aryl group may include a substituent.

The term “substitution” herein refers that any hydrogen in a hydrocarbon group may be substituted with at least one selected from the group consisting of a halogen atom, a C1-C6 alkyl group, a C2-C6 alkenyl group, a C2-C6 alkynyl group, a C1-C6 alkoxy group, a C1-C6 acetyl group, a C6-C12 phenoxy group, a C6-C12 aryl group, a C6-C12 alkylsulfonyl group, a sulfonic acid group, a hydroxy group, a nitro group, an amino group, an alkylamine group represented as —NR₃R₄R₅ (R₃, R₄ and R₅ are each independently hydrogen and or a C1-C6 alkyl group) and a cyano group.

For example, the quaternary alkyl ammonium hydroxide may include tetramethylammonium hydroxide, tetraethylammonium hydroxide, tetrapropylammonium hydroxide, tetrabutylammonium hydroxide, tetrahexylammonium hydroxide, tetraoctylammonium hydroxide, benzyltriethylammonium hydroxide, diethyldimethylammonium hydroxide, methyltributylammonium hydroxide, choline hydroxide, etc. These may be used alone or in a combination of two or more therefrom.

In example embodiments, a content of the quaternary alkyl ammonium hydroxide may be in a range from about 1 weight percent (wt %) to 20 wt % based on a total weight of the etchant composition. Within the above range, a degree of dissociation of hydroxide ions or an amount dissociated from the composition may be sufficiently provided, so that an performance may be improved. In an embodiment, the content of the quaternary alkyl ammonium hydroxide may be in a range from about 5 wt % to 10 wt % based on the total weight of the etchant composition.

The amine-based compound may adjust or maintain a pH of the etchant composition and may be added as an etching enhancer. For example, the amine-based compound may promote the dissociation or generation of hydroxide ions in the composition and may improve hydrophilization or wettability of a silicon layer. Additionally, the amine-based compound may promote removal of a surface hydrogen gas generated when etching the silicon layer.

The amine-based compound may include a hydroxy group or may not include a hydroxy group. If the amine-based compound contains the hydroxy group, a concentration of the hydroxide ions in the etchant composition may be increased and the etching rate of the etchant composition may be enhanced. The amine-based compound may have a linear structure or a cyclic structure.

For example, the amine-based compound containing the hydroxy group may include 1-amino-2-propanol, 2-amino-1-butanol, 3-amino-1-propanol, 3-amino-1,2-propanediol, 2,3-butanediol, methyldiethanolamine, propanolamine, ethanolamine, diethanolamine, N-methylethanolamine, N-methyldiethanolamine, 2-amino-3-methyl-1-butanol, 3-amino-2,2-dimethyl-1-propanol, tris(hydroxymethyl) aminomethane, 2-amino-2-methyl-1,3-propanediol, 3-methylamino-1-propanol, 2-dimethylamino-2-methyl-1-propanol, 1-dimethylamino-2-propanol, 3-dimethylamino-1-propanol, 2-dimethylamino-1-propanol, 2-diethylamino-1-propanol, 2-diethylamino-1-ethanol, 2-ethylamino-1-ethanol, 1-(dimethylamino)2-propanol, N-propyldiethanolamine, N-isopropyldiethanolamine, N-(2-methylpropyl)diethanolamine, N-n-butyldiethanolamine, N-t-butylethanolamine, N-cyclohexyldiethanolamine, 2-(dimethylamino)ethanol, 2-diethylaminoethanol, 2-dipropylaminoethanol, 2-butylaminoethanol, 2-t-butylaminoethanol, 2-cycloaminoethanol, 2-amino-2-pentanol, 2-[bis(2-hydroxyethyl)amino]-2-methyl-1-propanol, 2-[bis(2-hydroxyethyl)amino]-2-propanol, N,N-bis(2-hydroxypropyl)ethanolamine, 2-amino-2-methyl-1-propanol, tris(hydroxymethyl)aminomethane, triisopropanolamine, etc. These may be used alone or in a combination of two or more therefrom.

For example, the amine-based compound that does not contain a hydroxy group may include 1,2-diaminopropane, diethylenetriamine, isopropylamine, triethylamine, trimethylamine, methylamine, ethylamine, aniline (aminobenzene), 2-aminopentane, diethylamine, N-dodecyldiethylamine, etc. These may be used alone or in a combination of two or more therefrom.

The cyclic amine-based compound may include a hetero ring containing a substituted or unsubstituted nitrogen atom. For example, the cyclic amine-based compound may include a bridged bicyclic compound containing a substituted or unsubstituted nitrogen atom, or a heteroaryl group containing a substituted or unsubstituted nitrogen atom.

For example, the cyclic amine-based compound may include trimethylpyridine, dimethylpyridine, etc.

The cyclic amine-based compound may include an azabicyclo compound, a diazabicyclo compound, a triazabicyclo compound, etc., as the bridged bicyclic compound containing a nitrogen atom

In some embodiments, the azabicyclo compound may include an azabicycloalkane or an azabicycloalkene each having 3 to 13 carbon atoms. The diazabicyclo compound may include a diazabicycloalkane or a diazabicycloalkene each having 2 to 12 carbon atoms. The triazabicyclo compound may include a triazabicycloalkane or a triazabicycloalkene each having 2 to 11 carbon atoms.

For example, the cyclic amine-based compound may have a structure of one of azabicyclo-, diazabicyclo-, and triazabicyclo-, and may include at least one structure of -butane, -pentane, -hexane, -heptane, -octane, -nonane, -decane, -undecane, -dodecane, -tridecane, -tetradecane, -nonene, -decene and -undecene.

Examples of the cyclic amine-based compound may include a monoazabicyclo compound such as 8-azabicyclo[3.2.1]octane, 1,8-azabicyclo[6.3.2]tridecane, 11-azabicyclo[4.4.1]undecane-1,3,5,7,9-pentene, etc; a diazabicyclo compound such as 1,8-diazabicyclo[5.4.0]undec-7-ene, 1,5-diazabicyclo[4.3.0]non-5-ene, 2,8-diazabicyclo[4.3.0]nonane, 1,4-diazabicyclo[4.3.0]nonane, 1,4-diazabicyclo[3.2.2]nonane, 1,4-diazabicyclo[2.2.2]octane, 1,4-diazabicyclo[3.2.1]octane, 3-benzyl-3,8-compounds such as 1,5,7-diazabicyclo[3.2.1]octane, etc.; a triazabicyclo triazabicyclo[4.4.0]dec-5-ene, 7-methyl-1,5,7-triazabicyclo[4.4.0]dec-5-ene, etc. These may be used alone or in a combination of two or more therefrom.

In example embodiments, a content of the amine-based compound may be in a range from about 1 wt % to 30 wt % based on the total weight of the etchant composition. In some embodiments, the content of the amine-based compound may be in a range from about 5 wt % to 15 wt % based on the total weight of the etchant composition. Within the above range, the amine-based compound may hydrophilize the surface of the etching object, thereby improving the etching rate.

The silicon-etchant composition may include the nonionic surfactant. The nonionic surfactant may reduce a surface tension of the silicon layer to suppress foams and bubbles generated during the etching process.

In example embodiments, the nonionic surfactant may include: may include at least two selected from the group consisting of a first nonionic surfactant represented by Chemical Formula 1 where n is 1 to 2, a second nonionic surfactant represented by Chemical Formula 1 where n is 3 to 5 and a third nonionic surfactant represented by Chemical Formula 1 where n is 6 to 8.

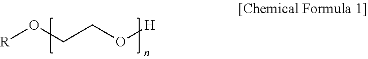

In Chemical Formula 1, R may be a C3 to C18 linear or branched alkyl group, a C3 to C18 cyclic alkyl group, or a C6 to C18 aryl group.

The branched alkyl group, the cyclic alkyl group and the aryl group may each independently be substituted or unsubstituted.

In Chemical Formula 1, R may be a hydrophobic group. The hydrophobic group may promote adsorption on the surface of the silicon layer to remove or desorb foams and bubbles generated during the etching process. The hydrophobic group may have a relatively low molecular weight structure to improve adsorption on the surface of the silicon layer. For example, R may be a linear or branched alkyl group, a cyclic alkyl group or an aryl group which have 10 carbon atoms or less.

For example, R may be the C3 to C18 linear or branched alkyl group such as a propyl group, an isopropyl group, a butyl group, an isobutyl group, a sec-butyl group, a tetrabutyl group, an ethyl hexyl group, a decyl group, a lauryl group, an isotridecyl group, a cetyl group, a stearyl group, etc.; the C3 to C18 cyclic alkyl groups such as a cyclopentyl group, a cyclohexyl group, a cycloheptyl group, a cyclooctyl group, etc.; the C6 to C18 aryl group such as a phenyl group, a naphthyl group, a methylphenyl group, an octylphenyl group, etc. In example embodiments, R may be the phenyl group, the naphthyl group, the methylphenyl group or the octylphenyl group. These may be used alone or in a combination of two or more therefrom.

In some embodiments, R may be the C3 to C18 cyclic alkyl group or the C6 to C18 aryl group. In one embodiment, R may be the C6 to C18 aryl group, e.g., the phenyl group.

In Chemical Formula 1, the polyethylene glycol group may represent a hydrophilic group. The hydrophilic group may improve penetration of the nonionic surfactant in the etchant composition. For example, while the nonionic surfactant being adsorbed to the surface of the silicon layer, penetration of the hydroxide ions may be promoted by the hydrophilic group.

Properties of the nonionic surfactant may vary depending on the repeated number (n) of the polyethylene glycol. For example, the first nonionic surfactant having n from 1 to 2 has a short hydrophilic group to enhance the etching rate without disturbing a contact between the surface of the etching object and the etchant composition.

The second nonionic surfactant having n from 3 to 5 may hydrophilize the surface of the etching object, thereby improving pattern penetration ability and etching performance of the etchant composition.

The third nonionic surfactant having n from 6 to 8 has a high surface hydrophilization efficiency of the etching object to reduce a surface roughness of the etching object.

The nonionic surfactant may include two or more types of the first nonionic surfactant to the second nonionic surfactant. Two or more types of the nonionic surfactants with different hydrophilic group lengths may be used, so that performance of the etchant composition may be improved in various aspects.

In example embodiments, the nonionic surfactant may include the second nonionic surfactant, and may further include the first nonionic surfactant or the third nonionic surfactant. In one embodiment, the nonionic surfactant may include the first nonionic surfactant, the second nonionic surfactant and the third nonionic surfactant.

In example embodiments, a content of the nonionic surfactant may be in a range from 0.01 wt % to 0.2 wt % based on the total weight of the composition. In some embodiments, the content of the nonionic surfactant may be in a range from 0.05 wt % to 0.15 wt % based on the total weight of the composition. Within the above range, the surface tension of the surface of the etching object may be effectively reduced, and thus a pattern penetration capability of the etchant composition may be increased.

In example embodiments, a weight ratio of the first nonionic surfactant to the second nonionic surfactant may be in a range from 0.1 to 0.2. In some embodiments, the weight ratio of the first nonionic surfactant to the second nonionic surfactant may be in a range from 0.12 to 0.17. Within the above range, the etching rate of the etchant composition may be increased while preventing an increase of the surface roughness of the etching object.

In example embodiments, a weight ratio of the third nonionic surfactant to the second nonionic surfactant may be in a range from 0.08 to 0.17. In some embodiments, a weight ratio of the third nonionic surfactant to the second nonionic surfactant may be in a range from 0.10 to 0.15. Within the above range, the pattern penetration of the etchant composition may not be decreased. Further, the nonionic surfactant may not be excessively adsorbed to the surface of the etching object so that a reduction of the etching rate may be prevented.

In example embodiments, the nonionic surfactant may not include a nonionic surfactant being represented by Chemical Formula 1 and having n of 8. In the case of the nonionic surfactant having n of 8 in Chemical Formula 1, the length of the hydrophilic group becomes long and an excessive adsorption on the surface of the etching object may be caused, thereby acting as an etch inhibitor

The etchant composition may include a remainder or a residual amount of water (e.g., deionized water). The term “remainder or residual amount” used herein may refer to a variable amount that varies according to an addition of a component or an agent. For example, a remaining amount excluding the quaternary alkyl ammonium hydroxide, the amine-based compound and the nonionic surfactant, or a remaining amount excluding the quaternary alkyl ammonium hydroxide, the amine-based compound, the nonionic surfactant and other additives may correspond to the remainder or residual amount.

In some embodiments, water may include deionized water for a semiconductor process. For example, deionized water having a resistivity value of 18 MΩ/cm or more may be used.

The etchant composition may further include an additive within a range that does not hinder the etching performance, the surface tension reduction, the bubble removal effect, etc., of the quaternary alkyl ammonium hydroxide, the amine-based compound and the nonionic surfactant. The additive may include, e.g., an etch enhancer, a corrosion inhibitor, a pH regulator, etc.

In some embodiments, a pH of the silicon etchant composition may be adjusted in a range from about 11 to 14. Within the pH range, damages to an insulation structure, a semiconductor pattern, a substrate, etc., other than the silicon etching object layer may be suppressed.

In some embodiments, the etchant composition described above may be prepared as a two-component type composition. For example, the amine-based compound and the nonionic surfactant may be mixed to prepare a preliminary etchant composition. The preliminary etchant composition may be mixed with the quaternary alkyl ammonium hydroxide aqueous solution. Accordingly, the silicon-etchant composition having a target content composition may be prepared from the preliminary etchant composition having a relatively high concentration.

Thus. the amine-based compound and the nonionic surfactant may be firstly mixed and stabilized, thereby preventing the amine-based compound and the nonionic surfactant from contacting the quaternary alkyl ammonium hydroxide in advance, and thus preventing an etching activity degradation.

In example embodiments, an etching rate of the silicon-etchant composition with respect to a single crystalline silicon layer may be greater than or equal to 4,000 Å/min. In some embodiments, the etching rate of the silicon-etchant composition with respect to the single crystalline silicon layer may be greater than or equal to 5,000 Å/min, or greater than or equal to 6,000 Å/min. Within the above range, an etching process may be effectively controlled while improving efficiency of the etching process and productivity.

An etching of the silicon layer may be performed by a method commonly known in the art using the above-described etchant composition. For example, in a batch type etching apparatus or a single type etching apparatus, a method using a deposition, a spray, etc., may be used. However, the etching method and conditions are not specifically limited, and may be properly controlled by those ordinarily skilled in the art.

FIGS. 1 to 7 are schematic cross-sectional views illustrating a method of forming a pattern in accordance with exemplary embodiments.

However, the etchant composition according to example embodiments is not limited to the process of FIGS. 1 to 7, and may be used to form various structures or patterns such as wirings, contacts, gates, etc.

FIGS. 1 to 3 are schematic cross-sectional views illustrating a method of manufacturing a semiconductor device in accordance with example embodiments.

Referring to FIG. 1, an insulating layer 110 may be formed on a substrate 100, and a silicon-containing layer 120 may be formed on the insulating layer 110. The substrate 100 may include a semiconductor material such as single crystalline silicon and single crystallin germanium, and may include polysilicon.

The insulating layer 110 may be formed to include an insulating material such as silicon oxide, silicon nitride, silicon oxynitride, polysiloxane, etc. For example, the insulating layer 110 may be formed by a chemical vapor deposition (CVD) process, a sputtering process, a physical vapor deposition (PVD) process, an atomic layer deposition (ALD) process, etc.

The silicon-containing layer 120 may include single crystalline silicon, polysilicon, or amorphous silicon.

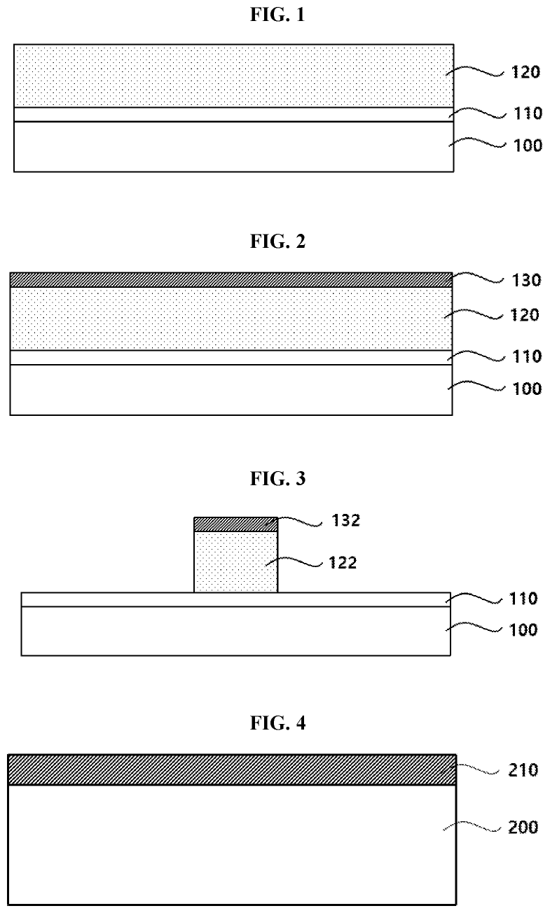

Referring to FIG. 2, a silicon protective layer 130 may be formed on the silicon-containing layer 120. The silicon protective layer 130 may be formed to include a silicon oxide layer or a silicon nitride layer. For example, the silicon protective layer 130 may be formed by a CVD process, a sputtering process, a PVD process, an ALD process, etc.

A mask pattern 132 may be formed by partially etching the silicon protective layer 130. For example, a portion of the silicon protective layer 130 may be partially etched until a portion of a top surface of the silicon-containing layer 120 is exposed.

Referring to FIG. 3, the silicon-containing layer 120 may be partially removed using the etchant composition according to the above-described example embodiments. Accordingly, a gate pattern 122 may be formed from the silicon-containing layer 120. FIGS. 4 to 7 are schematic cross-sectional views illustrating a method of forming

a pattern in accordance with example embodiments. Specifically, FIGS. 4 to 7 are schematic cross-sectional views illustrating a method of forming a shallow trench isolation (STI) according to example embodiments.

Referring to FIG. 4, a silicon protective layer 210 may be formed on a substrate 200.

The substrate 200 may be a silicon substrate containing single crystalline silicon, polysilicon or amorphous silicon.

The silicon protective layer 210 may include a silicon oxide layer or a silicon nitride layer. In this case, the silicon protective layer may be formed by a chemical vapor deposition (CVD) process, a sputtering process, a physical vapor deposition (PVD) process, an atomic layer deposition (ALD) process, etc. to cover a top surface of the substrate 200.

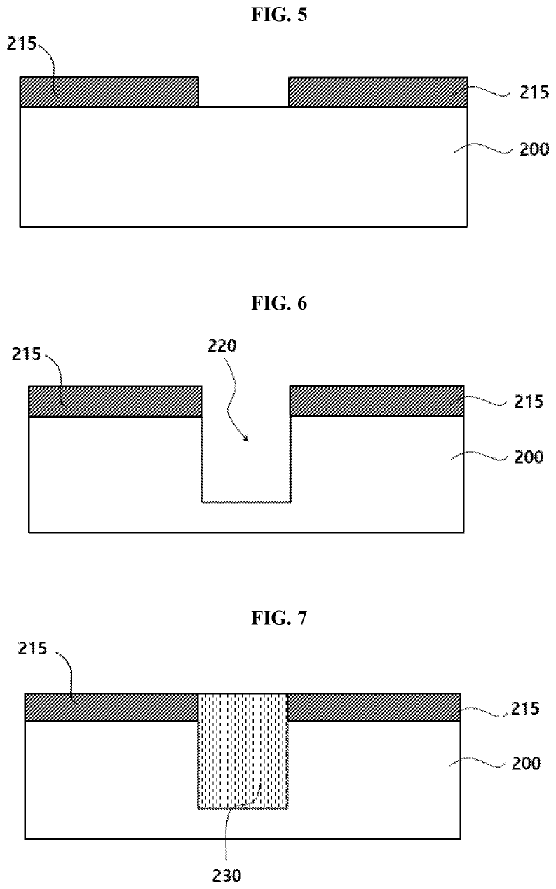

Referring to FIG. 5, the silicon protective layer 210 may be partially etched to form a mask pattern 215. For example, a portion of the silicon protective layer 210 may be etched until a portion of the top surface of the substrate 200 is exposed.

Referring to FIG. 6, an upper portion of the substrate 200 may be partially etched using the etchant composition according to the above-described example embodiments described. Accordingly, a trench 220 may be formed in the substrate 200.

As described above, the upper portion of the substrate 200 may only be selectively etched while preventing etching of the mask pattern 215 using the etchant composition. Thus, in, e.g., a nano-scale fine etching process, the upper portion of the substrate 200 may be removed without etching defects, and a highly reliable etching process may be performed.

Referring to FIG. 7, an insulating pattern 230 may be formed in the trench 220.

The insulating pattern 230 may be formed of an insulating material including silicon oxide, silicon nitride, silicon oxynitride, polysiloxane, etc. For example, the insulating material may be formed by a CVD process, a sputtering process, a PVD process, ALD process, etc., to fill an inside of the trench 220.

Hereinafter, preferred embodiments are provided to help understanding of the present invention, but these embodiments are merely illustrative of the present invention and do not limit the scope of the attached patent claims, and it is obvious to those skilled in the art that various changes and modifications to the embodiments are possible within the scope of the present invention. These modifications are to be interpreted as being within the scope of the attached claims.

### Examples and Comparative Examples

Silicon-etchant compositions were prepared as shown in Tables 1 and 2 below. A remainder of water was added in each composition to make 100 parts by weight of the composition.

TABLE 1

| | quaternary alkyl | | | | | |
|---|---|---|---|---|---|---|
| | ammonium | | nonionic surfactant | | amin-based | |
| Content | hydroxide | | component | | compound | |
| (weight part) | type | content | (weight ratio) | content | type | content |
| Example 1 | A-1 | 10 | B-2:B-1 = 1.00:0.10 | 0.1 | C-1 | 10 |
| Example 2 | A-1 | 10 | B-2:B-1 = 1.00:0.12 | 0.1 | C-1 | 10 |
| Example 3 | A-1 | 10 | B-2:B-1 = 1.00:0.17 | 0.1 | C-1 | 10 |
| Example 4 | A-1 | 10 | B-2:B-1 = 1.00:0.20 | 0.1 | C-1 | 10 |
| Example 5 | A-1 | 10 | B-2:B-3 = 1.00:0.08 | 0.1 | C-1 | 10 |
| Example 6 | A-1 | 10 | B-2:B-3 = 1.00:0.10 | 0.1 | C-1 | 10 |
| Example 7 | A-1 | 10 | B-2:B-3 = 1.00:0.15 | 0.1 | C-1 | 10 |
| Example 8 | A-1 | 10 | B-2:B-3 = 1.00:0.17 | 0.1 | C-1 | 10 |
| Example 9 | A-1 | 10 | B-2:B-1:B-3 = | 0.1 | C-1 | 10 |
| | | | 1.00:0.17:0.15 | | | |
| Example 10 | A-1 | 10 | B-2:B-1:B-3 = | 0.1 | C-1 | 10 |
| | | | 1.00:0.12:0.15 | | | |
| Example 11 | A-1 | 10 | B-2:B-1:B-3 = | 0.1 | C-1 | 10 |
| | | | 1.00:0.17:0.10 | | | |
| Example 12 | A-1 | 10 | B-2:B-1:B-3 = | 0.1 | C-1 | 10 |
| | | | 1.00:0.12:0.10 | | | |
| Example 13 | A-1 | 10 | B-2:B-1:B-3:B-4 = | 0.1 | C-1 | 10 |
| | | | 1.00:0.17:0.15:0.10 | | | |
| Example 14 | A-1 | 10 | B-2:B-1 = 1.00:0.12 | 0.2 | C-1 | 10 |
| Example 15 | A-1 | 5 | B-2:B-1 = 1.00:0.12 | 0.1 | C-1 | 10 |
| Example 16 | A-2 | 10 | B-2:B-1 = 1.00:0.12 | 0.1 | C-1 | 10 |
| Example 17 | A-1 | 10 | B-2:B-1 = 1.00:0.12 | 0.1 | C-1 | 20 |
| Example 18 | A-1 | 10 | B-2:B-1 = 1.00:0.12 | 0.1 | C-2 | 10 |
| Example 19 | A-1 | 10 | B-3:B-1 = 1.00:1.00 | 0.1 | C-1 | 10 |

TABLE 2

| | quaternary alkyl | | | | | |
|---|---|---|---|---|---|---|
| | ammonium | | nonionic surfactant | | amin-based | |
| Content | hydroxide | | component | | compound | |
| (weight part) | type | content | (weight ratio) | content | type | content |
| Comparative | A-1 | 10 | B-2 | 0.1 | C-1 | 10 |
| Example 1 | | | | | | |
| Comparative | A-1 | 10 | B-1 | 0.1 | C-1 | 10 |
| Example 2 | | | | | | |
| Comparative | A-1 | 10 | B-3 | 0.1 | C-1 | 10 |
| Example 3 | | | | | | |
| Comparative | A-1 | 10 | B-4 | 0.1 | C-1 | 10 |
| Example 4 | | | | | | |
| Comparative | A-1 | 10 | B-5 | 0.1 | C-1 | 10 |
| Example 5 | | | | | | |
| Comparative | A-1 | 10 | B-6 | 0.1 | C-1 | 10 |
| Example 6 | | | | | | |
| Comparative | A-1 | 10 | B-7 | 0.1 | C-1 | 10 |
| Example 7 | | | | | | |
| Comparative | A-1 | 10 | B-8 | 0.1 | C-1 | 10 |
| Example 8 | | | | | | |
| Comparative | A-1 | 10 | B-2:B-7 = 1.00:0.10 | 0.1 | C-1 | 10 |
| Example 9 | | | | | | |
| Comparative | — | — | B-2:B-1 = 1.00:0.10 | 0.1 | C-1 | 10 |
| Example 10 | | | | | | |
| Comparative | A-1 | 10 | B-2:B-1 = 1.00:0.10 | 0.1 | — | — |
| Example 11 | | | | | | |

The components listed in Table 1 and Table 2 are as follows.
A-1: tetramethylammonium hydroxide
A-2: Tetraethylammonium hydroxide
B-1: polyethylene glycol phenyl ether, n=2
B-2: polyethylene glycol phenyl ether, n=4
B-3: polyethylene glycol phenyl ether, n=6
B-4: polyethylene glycol phenyl ether, n=8
B-5: polyethylene glycol beta-naphthyl ether, n=4
B-6: polyethylene glycol lauryl ether, n=4
B-7: polyethylene glycol tert-octyl phenyl ether, n=10
B-8: polyethylene glycol oleyl ether, n=4
C-1: 1-amino-2-propanol
C-2: 2,3-butanediol

### Experimental Example 1: Evaluation on Etch Rate for Silicon

A silicon wafer on which silicon was deposited to a thickness of 6000 Å was cut to a size of 1.5 cm×1.5 cm to prepare a sample. The sample was immersed in the etchant compositions of Examples and Comparative Examples for 30 seconds at 70° C. and 400 rpm.

Thereafter, the sample was taken out, washed with water, and dried in an air. A thickness of the silicon layer was measured using Ellipsometer, and an etching rate of the silicon layer was calculated based on a change of the layer thickness before and after the immersion. The etch rate was evaluated based on the following criteria.

### <Evaluation Criteria>

⊚⊚: etch rate 6000 Å/min or more
⊚: etch rate less than 6000 Å/min˜5000 Å/min or more
◯: etch rate less than 5000 Å/min˜4000 Å/min or more
Δ: Etching rate less than 4000 Å/min˜3000 Å/min or more
X: etch rate less than 3000 Å/min

### Experimental Example 2: Evaluation on Surface Roughness after Etching of Silicon

A surface roughness (Rq, Root Mean Square) of the silicon wafer after the etching in Experimental Example 1 was measured using an AFM (Atomic Force Microscopy). The surface roughness was evaluated based on the following criteria.

### <Evaluation Criteria>

⊚: 10 Å or less
◯: More than 10 Å˜30 Å or less
Δ: More than 30 Å˜50 Å or less
X: greater than 50 Å

### Experimental Example 3: Evaluation on Silicon Pattern Etching Uniformity

Etch rates of two patterns having an aspect ratio of about 20 (pattern A: about 50 nm CD, pattern B: about 100 nm CD) were compared to evaluate an etching uniformity according to a difference of penetration capability of the etchant composition.

A silicon etching rate in each pattern was obtained, and the etching uniformity was calculated according to the following equation, and the etching uniformity was evaluated based on the following criteria

Etching uniformity=(pattern B etch rate-pattern A etch rate)/(pattern B etch rate+pattern A etch rate) [Equation]

### <Evaluation Criteria>

⊚: 0.3 or less
◯: greater than 0.3 to less than 0.5
Δ: greater than 0.5 to less than 0.7
X: More than 0.7

### Experimental Example 4: Evaluation on Nonionic Surfactant Residue

To evaluate a silicon surface residue, the sample from which the etching evaluation was completed was prepared and an FT-IR analysis was performed. Polyethylene oxide derived from the nonionic surfactant was analyzed to evaluate a residue of the nonionic surfactant based on the following criteria.

### <Evaluation Criteria>

X: No residue
◯: Residue was detected

The evaluation results are shown in Tables 3 and 4.

TABLE 3

| | | surface | | |
|---|---|---|---|---|
| | | roughness | pattern | |
| | silicon etch | after etching | etching | surface |
| | rate (Å/min) | (Å) | uniformity | residue |
| Example 1 | ◯ | ◯ | ◯ | X |
| Example 2 | ⊚⊚ | ◯ | ◯ | X |
| Example 3 | ⊚⊚ | ◯ | ◯ | X |
| Example 4 | ⊚⊚ | Δ | Δ | X |
| Example 5 | ◯ | ◯ | ◯ | X |
| Example 6 | ◯ | ⊚ | ⊚ | X |
| Example 7 | ◯ | ⊚ | ⊚ | X |
| Example 8 | Δ | ⊚ | ⊚ | X |
| Example 9 | ⊚⊚ | ⊚ | ⊚ | X |
| Example 10 | ⊚⊚ | ⊚ | ⊚ | X |
| Example 11 | ⊚⊚ | ⊚ | ⊚ | X |
| Example 12 | ⊚⊚ | ⊚ | ⊚ | X |
| Example 13 | Δ | ⊚ | ⊚ | X |
| Example 14 | ⊚⊚ | ◯ | ◯ | X |
| Example 15 | ⊚⊚ | ◯ | ◯ | X |
| Example 16 | ⊚⊚ | ◯ | ◯ | X |
| Example 17 | ⊚ | ◯ | ◯ | X |
| Example 18 | ⊚⊚ | ◯ | ◯ | X |
| Example 19 | Δ | ◯ | ◯ | X |

TABLE 4

| | | surface | | |
|---|---|---|---|---|
| | | roughness | pattern | |
| | silicon etch | after etching | etching | surface |
| | rate (Å/min) | (Å) | uniformity | residue |
| Comparative | ⊚ | ◯ | X | X |
| Example 1 | | | | |
| Comparative | ⊚⊚ | X | X | X |
| Example 2 | | | | |
| Comparative | X | ⊚ | ⊚ | X |
| Example 3 | | | | |
| Comparative | X | ⊚ | ⊚ | X |
| Example 4 | | | | |
| Comparative | Δ | ⊚ | ◯ | ◯ |
| Example 5 | | | | |
| Comparative | ⊚ | X | Δ | X |
| Example 6 | | | | |
| Comparative | X | ⊚ | ⊚ | ◯ |
| Example 7 | | | | |
| Comparative | X | ⊚ | ⊚ | ◯ |
| Example 8 | | | | |
| Comparative | X | ⊚ | ⊚ | ◯ |
| Example 9 | | | | |
| Comparative | X | ⊚ | ⊚ | X |
| Example 10 | | | | |
| Comparative | Δ | Δ | Δ | X |
| Example 11 | | | | |

Referring to Tables 1 to 4, no etch residue was generated on the surface of the etching object and the etch rate was increased in Examples. Further, the pattern etching uniformity was improved and the surface roughness of the silicon wafer was reduced.

In Comparative Examples 1 to 8 where the silicon etchant composition including one type of the nonionic surfactant was used, the silicon etch uniformity was degraded, the etch rate was excessively reduced, or the etch residue was generated on the wafer surface.

In Comparative Example 9 where the second nonionic surfactant was included, but the first nonionic surfactant or the third nonionic surfactant was not used in the etchant composition, the surface residue was generated and the etch rate was lowered.

In Comparative Examples 10 and 11 where the silicon etchant composition did not include the quaternary alkyl ammonium hydroxide or the amine-based compound, the etch rate, the surface roughness and the pattern etch uniformity were all degraded.

What is claimed is:

1. A silicon-etchant composition comprising:
a quaternary alkyl ammonium hydroxide;
an amine-based compound; and
a nonionic surfactant comprising at least two selected from the group consisting of a first nonionic surfactant represented by Chemical Formula 1 where n is 1 to 2, a second nonionic surfactant represented by Chemical Formula 1 where n is 3 to 5, a third nonionic surfactant represented by Chemical Formula 1 where n is 6 to 8: 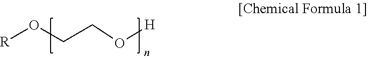
wherein R is a C3 to C18 linear or branched alkyl group, a C3 to C18 cyclic alkyl group, or a C6 to C18 aryl group.

2. The silicon-etchant composition of claim 1, wherein the nonionic surfactant includes the second nonionic surfactant, and further includes at least one of the first nonionic surfactant and the third nonionic surfactant.

3. The silicon-etchant composition of claim 1, wherein a content of the nonionic surfactant is in a range from 0.01 wt % to 0.2 wt % based on a total weight of the composition.

4. The silicon-etchant composition of claim 2, wherein the nonionic surfactant includes the first nonionic surfactant and the second nonionic surfactant, and
a weight ratio of the first nonionic surfactant to the second nonionic surfactant is in a range from 0.1 to 0.2.

5. The silicon-etchant composition of claim 4, wherein a weight ratio of the first nonionic surfactant to the second nonionic surfactant is in a range from 0.12 to 0.17.

6. The silicon-etchant composition of claim 2, wherein the nonionic surfactant includes the second nonionic surfactant and the third nonionic surfactant, and
a weight ratio of the third nonionic surfactant to the second nonionic surfactant is in a range from 0.08 to 0.17.

7. The silicon-etchant composition of claim 6, wherein a weight ratio of the third nonionic surfactant to the second nonionic surfactant is in a range from 0.10 to 0.15.

8. The silicon-etchant composition of claim 1, wherein the nonionic surfactant does not include a nonionic surfactant represented by Chemical Formula 1 where n is 8.

9. The silicon-etchant composition of claim 1, wherein, in Chemical Formula 1, R is a phenyl group, a naphthyl group, a methylphenyl group or an octylphenyl group.

10. The silicon-etchant composition of claim 1, wherein a content of the quaternary alkyl ammonium hydroxide is in a range from 1 wt % to 20 wt % based on a total weight of the composition.

11. The silicon-etchant composition of claim 1, wherein a content of the amine-based compound is in a range from 1 wt % to 30 wt % based on a total weight of the composition.

12. A method of forming a pattern, comprising:
forming a silicon-containing layer on a substrate;
partially forming a silicon protective layer on the silicon-containing layer; and
etching the silicon-containing layer using the silicon-etchant composition of claim 1.

13. The method of claim 12, wherein the silicon protective film is used as an etch mask.

14. The method of claim 12, wherein etching the silicon-containing layer comprises forming a gate pattern by etching the silicon-containing layer.
